(19) United States
(12) Patent Application Publication
(10) Pub. No.: US 2025/0056815 A1
(43) Pub. Date: Feb. 13, 2025

(54) SYSTEMS AND METHODS FOR NON-UNIFORM MEMORY ACCESS ON THREE-DIMENSIONALLY-STACKED HYBRID MEMORY

(71) Applicant: Meta Platforms Technologies, LLC, Menlo Park, CA (US)

(72) Inventors: Lita Yang, Sunnyvale, CA (US); Huseyin Ekin Sumbul, San Francisco, CA (US); Fan Wu, Redwood City, CA (US); Edith Dallard, San Mateo, CA (US); Huichu Liu, Santa Clara, CA (US); Daniel Henry Morris, Mountain View, CA (US)

(21) Appl. No.: 18/391,007

(22) Filed: Dec. 20, 2023

Related U.S. Application Data
(60) Provisional application No. 63/518,046, filed on Aug. 7, 2023.

(51) Int. Cl. H10B 80/00; G06N 3/063; H01L 23/00; H01L 25/00; H01L 25/065; H01L 25/18

(52) U.S. Cl. CPC H10B 80/00; G06N 3/063; H01L 24/08; H01L 24/80; H01L 25/0657; H01L 25/18; H01L 25/50; H01L 2224/08145; H01L 2224/80895; H01L 2224/80896; H01L 2225/06541; H01L 2924/1431; H01L 2924/1436; H01L 2924/1437

(57) ABSTRACT

A method for non-uniform memory access on three-dimensionally-stacked hybrid memory may include providing a logic die including a circuit and a memory. The method may additionally include providing a plurality of memory dies including an additional memory. The method may also include stacking the logic die and the plurality of memory dies three-dimensionally using face-to-face hybrid bonds that provide non-uniform access to the additional memory by the circuit. Various other methods, systems, and computer-readable media are also disclosed.

### CROSS REFERENCE TO RELATED APPLICATION

This application claims the benefit of U.S. Provisional Application No. 63/518,046, filed Aug. 7, 2023, the disclosure of which is incorporated, in its entirety, by this reference.

### BRIEF DESCRIPTION OF DRAWINGS

The accompanying drawings illustrate a number of exemplary embodiments and are a part of the specification. Together with the following description, these drawings demonstrate and explain various principles of the present disclosure.

FIG. 1 is a flow diagram of an exemplary method for non-uniform memory access on three-dimensionally-stacked hybrid memory.

FIG. 2 is a graphical illustration of exemplary image signal processor workload dynamic random access memory average bandwidth and footprint requirements.

FIG. 3 is a graphical illustration of an exemplary overall power consumption breakdown of image signal processor workloads compared across different memory configurations.

FIG. 4 is an illustration of an exemplary architecture of a non-uniform memory access across two dies.

FIG. 5 is a graphical illustration of exemplary relative energy access benefits for two-dimensional and three-dimensional memory designs.

FIG. 6 is an illustration of exemplary memory technology options considered and proposed for image signal processing hardware.

FIG. 7 is a graphical illustration of an exemplary memory power comparison between three-dimensional static random access memory and wide input-output dynamic random access memory versus a two-dimensional image signal processor baseline.

FIG. 8 is a graphical illustration of an exemplary three-dimensional image signal processor architecture figure of merit that evaluates power improvement with respect to area footprint.

FIG. 9 is a graphical illustration of an exemplary comparison of power consumption versus memory capacity across two different types of additional memory for different partitions of the additional memory.

FIG. 10 is an illustration of exemplary augmented-reality glasses that may be used in connection with embodiments of this disclosure.

FIG. 11 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Augmented reality and virtual reality glasses (e.g., VR headsets, AR glasses, etc.) often benefit from inclusion of neural network accelerators. A neural network (NN) accelerator is a processor that is optimized specifically to handle neural network workloads. Such accelerators cluster and classify data efficiently and at a fast rate. NN accelerators may be implemented in AR/VR glasses and process images rendered to one or more display devices.

Modern system-on-chip (SoC) design for AR/VR edge devices consists of multiple subsystems (e.g., camera interface, machine learning accelerator, GPU, CPU, etc.) sharing a large memory (usually SRAM) to pass data between the subsystems. These large, shared memories (e.g., 32+MB) that have equal latencies for all ports and memory endpoints cannot be designed with low energy/access due to large clock tree power and pipelining to overcome the large physical distances signals must travel. 3D stacked memories have been used to increase the memory capacities of such SoCs while maintaining the same X and Y form-factor (i.e., area footprint). These 3D stacked memories (i.e., multiple dies of SRAM stacked directly on top of each other), however, are accessed via a separate connection that cannot simultaneously serve multiple subsystems, thus yielding lower bandwidth connections to memories on other dies compared to the same die. Typically, these memories also require data to be serialized and then de-serialized in order to transfer data from one die to another, which is a power-hungry process.

The present disclosure is generally directed to systems and methods for non-uniform memory access on three-dimensionally stacked hybrid memory. For example, a semiconductor device can include a logic die that has a circuit and a memory, and a plurality of memory dies providing an additional memory. The logic die and the plurality of memory dies can be stacked three-dimensionally using face-to-face hybrid bonds that provide non-uniform access to the additional memory by the circuit. This non-uniform access can allow one or more subsystem of the circuit to have equal bandwidth access to a plurality of memory banks of the additional memory but with a reduced latency in accessing one or more memory banks of the plurality of memory banks compared to a latency in accessing one or more other memory banks of the plurality of memory banks. This non-uniform access can be implemented using direct flip-flop to flip-flop connections across dies.

Further, the additional memory can include a first type of additional memory (e.g., static random access memory (SRAM)) and a second type of additional memory (e.g., wide input-output dynamic random access memory (WIO-DRAM)). The types of additional memory can be determined by comparing different memory settings according to a metric that evaluates power improvement with respect to area footprint. Further still, a partition of the different types of additional memory can be determined by comparing different partitions according to a metric that evaluates power consumption with respect to memory capacity. For example, the partition can be determined for an additional memory having a memory capacity no greater than twenty-five megabytes as the first type of additional memory (e.g., SRAM) comprising no more than fifty percent of the additional memory and the second type of additional memory (e.g., WIO-DRAM) comprising no more than fifty percent of the additional memory. Alternatively or additionally, the partition can be determined for an additional memory having a memory capacity no less than twenty-five megabytes as the first type of additional memory (e.g., SRAM) comprising no more than twenty-five percent of the additional memory, and the second type of additional memory (e.g., WIO-DRAM) comprising no more than seventy-five percent of the additional memory. The partition can be determined statically (e.g., before runtime) and/or dynamically (e.g., during runtime) to support multiple use cases and memory requirements.

Implementations of the disclosed systems and methods can utilize a high density three-dimensional (3D) interconnect enabled by hybrid bonding to create a seamless shared memory, with non-uniform access times and high bandwidth connections to SRAMs in 3D memory stacks. These implementations can utilize hybrid bonding to create high bandwidth, parallel connections to neighboring dies with equal bandwidth and access energy compared to conventional on-chip connections. The non-uniform access time can allow for subsystems physically located closer to certain memory (e.g., SRAM) banks to have lower latencies but equal bandwidth access to all SRAM banks in the multi-die stack. The non-uniform access time can allow multiple compute units to access a slice of a shared memory at reduced latency/energy compared to a large traditional memory with equal access latency/energy for all memory locations. For example, the energy and latency to access memory two router hops away can be the same, regardless of whether both routers are on the same die or on different dies. Moreover, the bandwidth between two routers can be the same, regardless of whether the routers are located on different dies or the same die. These implementations can be extendable to multiple die stacks without compromising any given subsystem's access energy to its closest memory banks or the overall bandwidth to each memory bank in the 3D stack. The implementations can avoid use of serialize-deserialize circuits (SerDes) when communicating across dies but can use instead a direct flip-flop to flip-flop connection, minimizing the energy to transmit data across dies.

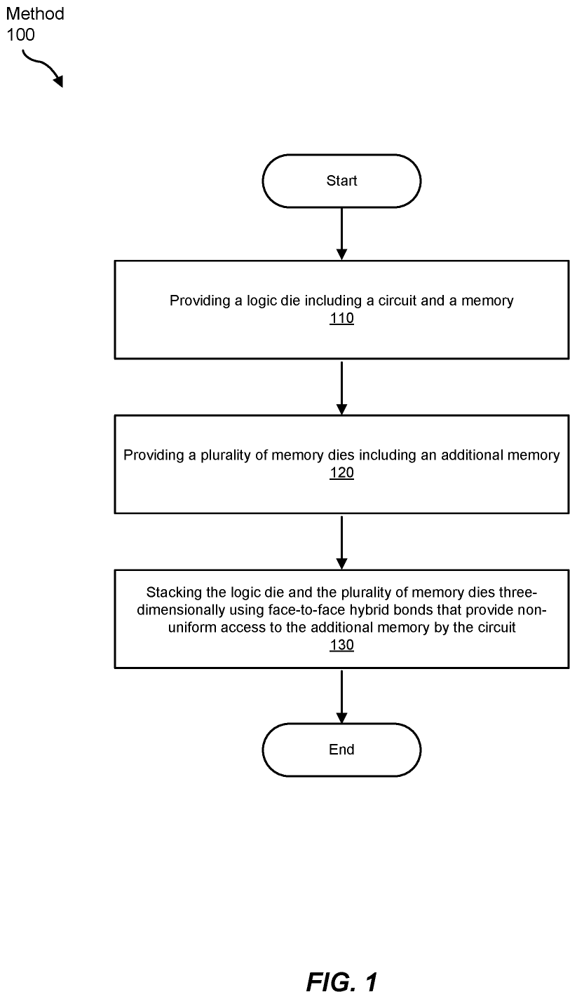

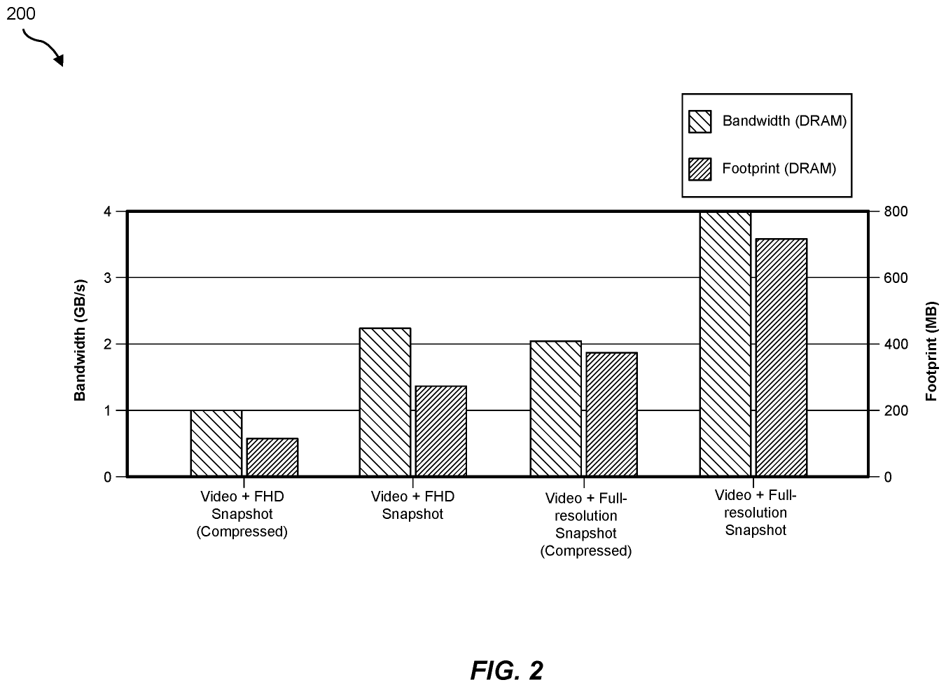

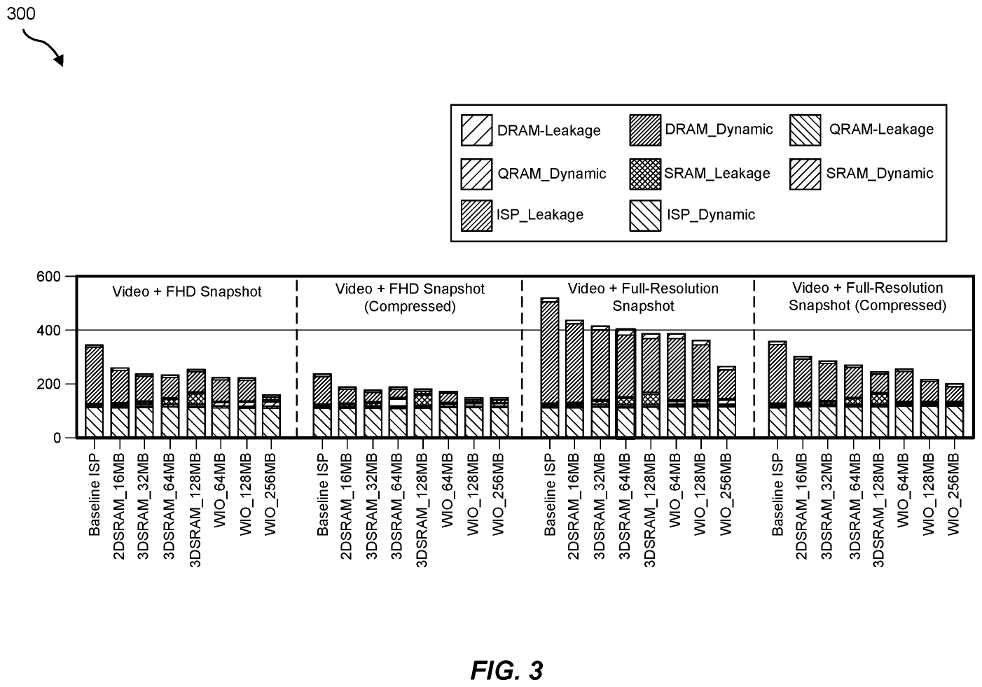

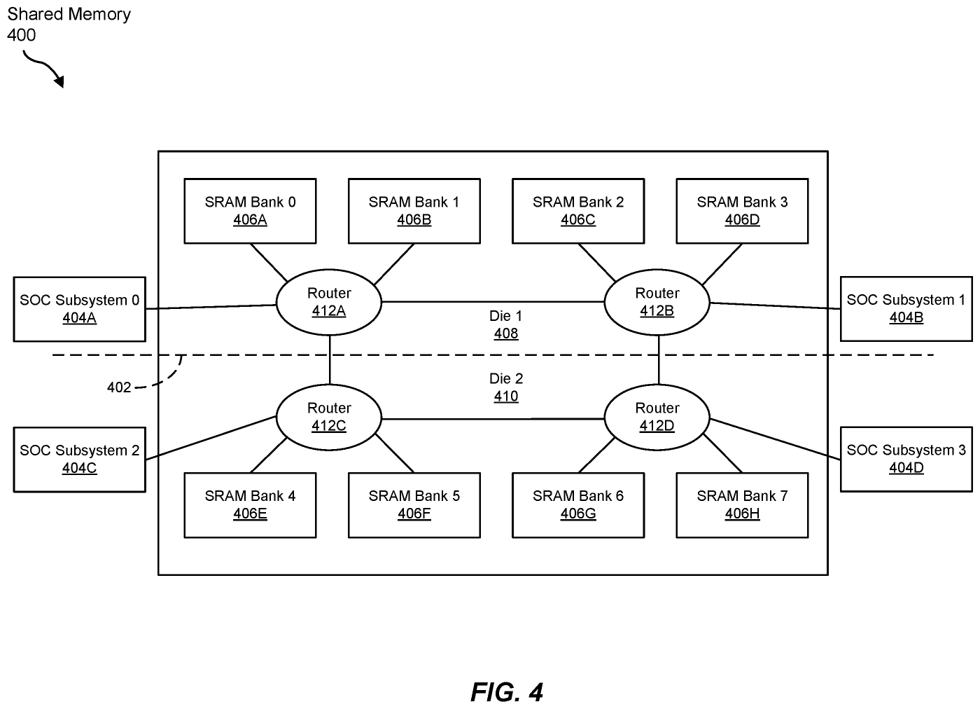

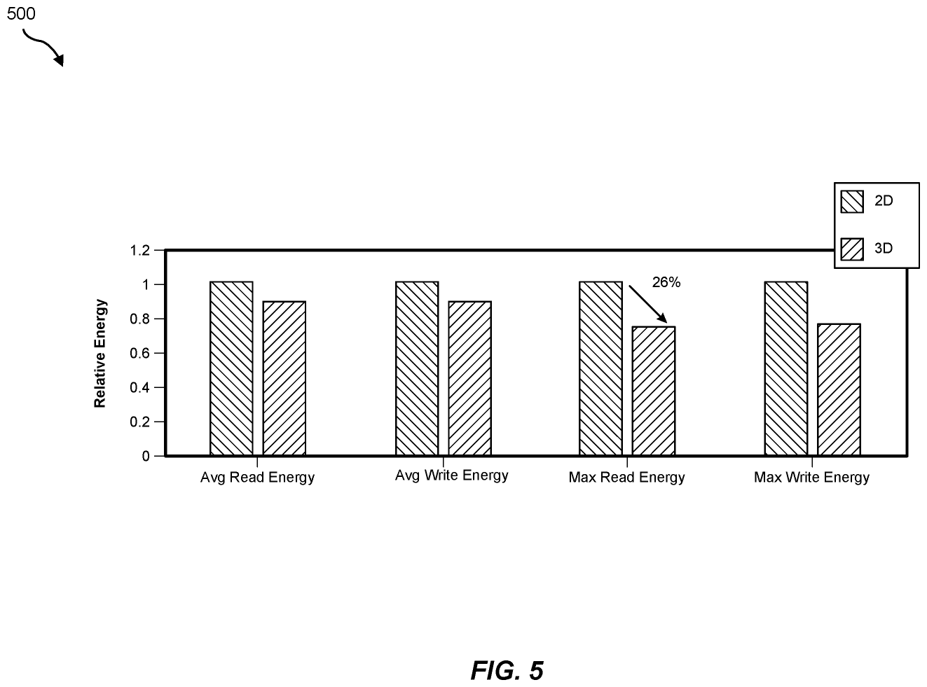

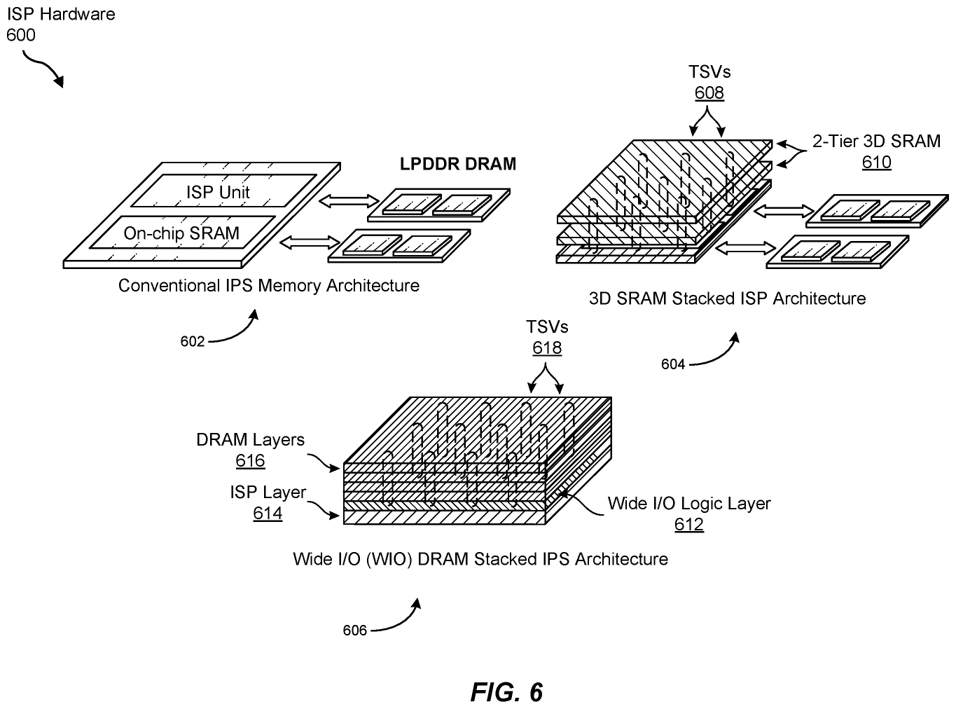

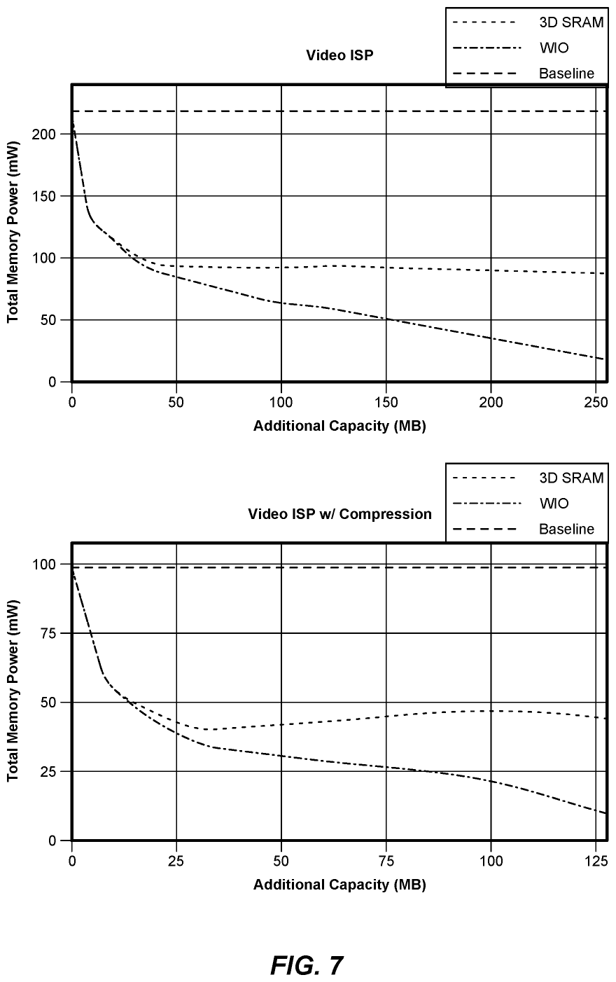

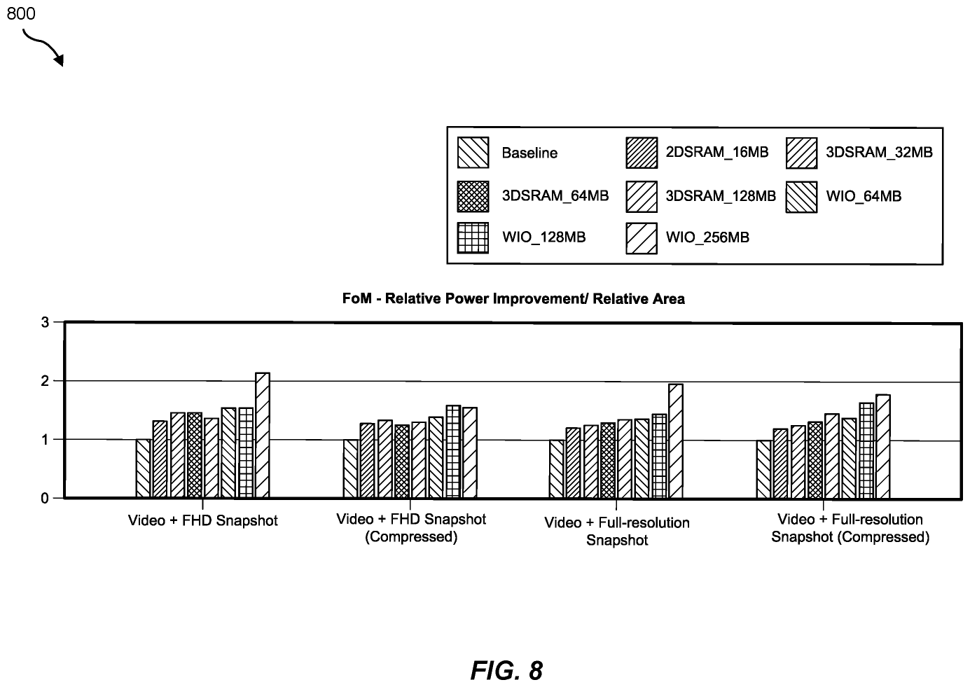

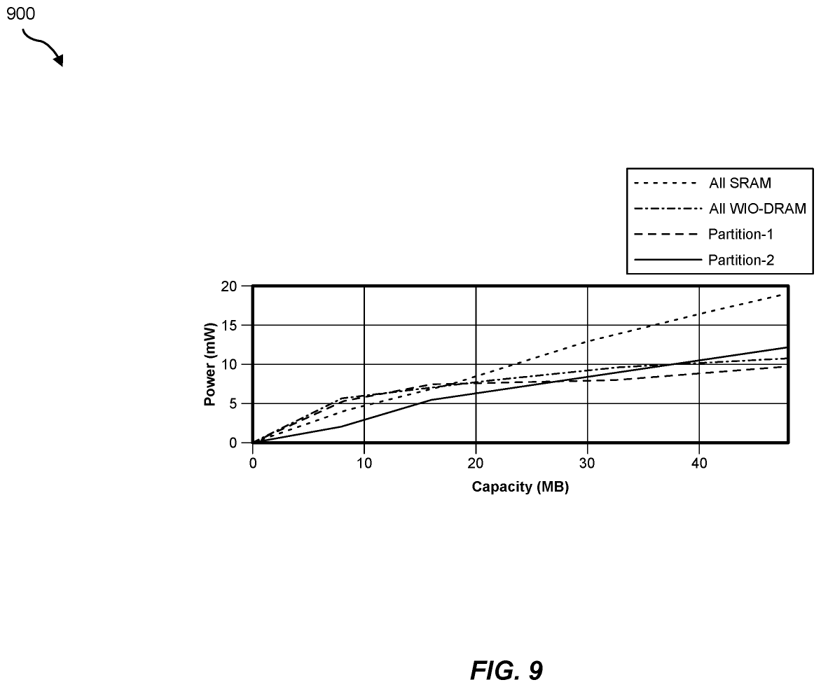

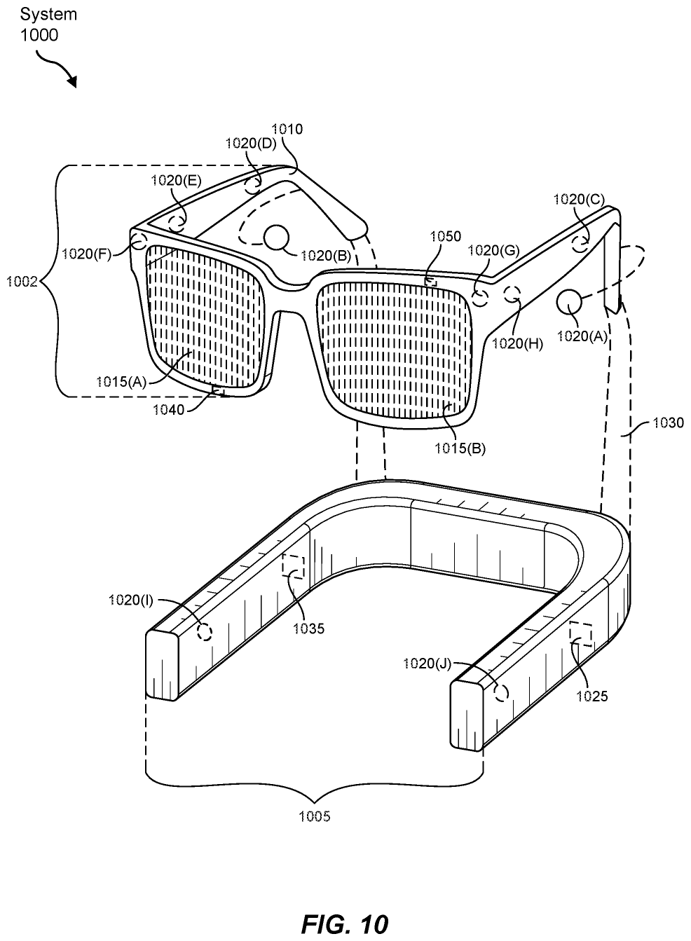

The following will provide, with reference to FIG. 1, detailed descriptions of exemplary methods for non-uniform memory access on three-dimensionally-stacked hybrid memory. Detailed descriptions of exemplary image signal processor workload dynamic random access memory average bandwidth and footprint requirements are also provided with reference to FIG. 2. Additionally, detailed descriptions of an exemplary overall power consumption breakdown of image signal processor workloads compared across different memory configurations are provided with reference to FIG. 3. Further, detailed descriptions of an exemplary architecture of a non-uniform memory access across two dies are provided with reference to FIG. 4. Further, detailed descriptions of exemplary relative energy access benefits for two-dimensional and three-dimensional memory designs are provided with reference to FIG. 5. Further, detailed descriptions of exemplary memory technology options considered and proposed for image signal processing hardware are provided with reference to FIG. 6. Further, detailed descriptions of an exemplary memory power comparison between three-dimensional SRAM and WIO-DRAM versus a two-dimensional image signal processor baseline are provided with reference to FIG. 7. Further, detailed descriptions of an exemplary three-dimensional image signal processor architecture figure of merit that evaluates power improvement with respect to area footprint are provided with reference to FIG. 8. Further, detailed descriptions of an exemplary comparison of power consumption versus memory capacity across two different types of additional memory for different partitions of the additional memory are provided with reference to FIG. 9. Finally, detailed descriptions of exemplary augmented-reality glasses and virtual-reality headsets are provided with reference to FIGS. 9 and 10.

FIG. 1 is a flow diagram of an exemplary method 100 for non-uniform memory access on three-dimensionally-stacked hybrid memory. Beginning at step 110, method 100 may include providing a logic die. For example, step 110 may include providing a logic die including a circuit and a memory.

The term “die,” as used herein, may generally refer to a thin piece of silicon. For example, and without limitation, a die may include a thin piece of silicon on which components, such as transistors, diodes, resistors, and other components, are housed to fabricate a functional electronic circuit. In this context, a “logic die” may correspond to a die that contains a majority of the logic components (e.g., transistors) of the electronic circuit of a semiconductor device. In contrast, a “memory die” may correspond to a die that contains a majority of the memory components (e.g., SRAM, DRAM, etc.) of the electronic circuit of a semiconductor device.

The term “circuit,” as used herein, may generally refer to a complete circular path through which electricity flows. For example, and without limitation, a simple circuit may include a current source, conductors, and a load. The term circuit can be used in a general sense to refer to any fixed path through which electricity, data, or a signal can travel. One example type of circuit may be a neural network accelerator.

The term “memory,” as used herein, may generally refer to an electronic holding place for instructions and/or data used by a computer processor to perform computing functions. For example, and without limitation, a memory may correspond to MOS memory, volatile memory, non-volatile memory, and/or semi-volatile memory. Example types of memory may include static random access memory (SRAM) and/or dynamic access random memory (DRAM).

Step 110 may be performed in a variety of ways. In one example, the circuit of the logic die provided in step 110 may correspond to a processor of a neural network accelerator. Additionally or alternatively, the memory of the logic die provided in step 110 may include static random access memory (SRAM).

At step 120, method 100 may include providing a plurality of memory dies. For example, step 120 may include providing a plurality of memory dies including an additional memory.

Step 120 may be performed in a variety of ways. In one example, the additional memory may include a first type of additional memory and a second type of additional memory. In some of these implementations, the first type of additional memory may correspond to static random access memory (SRAM) and the second type of additional memory may correspond to wide input-output dynamic random access memory (WIO-DRAM). In some of these examples, the additional memory may have a memory capacity no greater than twenty-five megabytes, the first type of additional memory may comprise no more than fifty percent of the additional memory, and the second type of additional memory may comprise no more than fifty percent of the additional memory. In others of these examples, the additional memory may have a memory capacity no less than twenty-five megabytes, the first type of additional memory may comprise no more than twenty-five percent of the additional memory, and the second type of additional memory may comprise no more than seventy-five percent of the additional memory. In some implementations, method 100 may, at step 120, select the first type of additional memory and the second type of additional memory by comparing different memory settings according to a metric that evaluates power improvement with respect to area footprint. In additional or alternative implementations, method 100 may, at step 120, select the partition of the first type of additional memory and the second type of additional memory by comparing different partitions according to a metric that evaluates power consumption with respect to memory capacity.

At step 130, method 100 may include stacking the logic die and the plurality of memory dies. For example, step 130 may include stacking the logic die and the plurality of memory dies three-dimensionally using face-to-face hybrid bonds that provide non-uniform access to the additional memory by the circuit.

The term “stacking,” as used herein, may generally refer to vertically arranging two or more integrated circuit dies one atop another. For example, and without limitation, multiple integrated circuits may be stacked vertically using, for example, through silicon via and/or copper to copper (Cu—Cu) connections so that they behave as a single device to achieve performance improvements at reduced power and smaller footprint compared to conventional two-dimensional processes.

The term “die-to-die data communication,” as used herein, may generally refer to a data interface between dies of a semiconductor device. For example, and without limitation, die-to-die data communication may be achieved using through silicon via, wires, direct bonding, hybrid bonding, etc.

The term “face-to-face,” as used herein, may generally refer to a bonding style in three-dimensional integrated circuits (3D ICs). For example, and without limitation, face-to-face bonding may bond integrated circuits by using the top-metals (e.g., faces) of two integrated circuits as the bonding sides when stacking the two integrated circuits. In contrast, face-to-back bonding may bond integrated circuits by using the top-metal (e.g., face) of only one of two integrated circuits as the bonding side when stacking the two integrated circuits.

The term “hybrid bonds,” as used herein, may generally refer to an extremely fine pith Cu—Cu interconnect between stacked dies. For example, and without limitation, hybrid bonding may include stacking one die atop another die with extremely fine pitch Cu—Cu interconnect used to provide the connection between these dies.

The term “non-uniform access,” as used herein, may generally refer to an ability to read information from different memory banks with non-uniform access times (e.g., different latencies). For example, and without limitation, this non-uniform access time may allow for subsystems physically located closer to certain memory (e.g., SRAM) banks to have lower latencies but equal bandwidth access to all SRAM banks in a multi-die stack. In this context, this non-uniform access time may also allow multiple compute units to access a slice of a shared memory at reduced latency/energy compared to a large traditional memory with equal access latency/energy for all memory locations.

Step 130 may be performed in a variety of ways. In one example, the non-uniform access may allow one or more subsystem of the circuit to have equal bandwidth access to a plurality of memory banks of the additional memory but with a reduced latency in accessing one or more memory banks of the plurality of memory banks compared to a latency in accessing one or more other memory banks of the plurality of memory banks. Additionally or alternatively, a latency experienced by a subsystem of the circuit in accessing a memory bank of the additional memory that is a first number of router hops (e.g., less than a second number of router hops) away from the subsystem may be less than a latency experienced by the subsystem in accessing an additional memory bank of the additional memory that is the second number of router hops away from the subsystem. Additionally or alternatively, a first set of energy, latency, and bandwidth experienced by a subsystem of the circuit in accessing a first memory bank of the additional memory that is a given number of router hops away from the subsystem may be equal to a second set of energy, latency, and bandwidth experienced by the subsystem in accessing a second memory bank of the additional memory that is the given number of router hops away from the subsystem. In some of these implementations, a first set of energy, latency, and bandwidth may be equal to a first set of energy, latency, and bandwidth regardless of whether a first plurality of routers used to access the first memory bank and a second plurality of routers used to access the second memory bank are implemented on a same die, on different dies, or combinations thereof. In one or more additional or alternative examples, method 100 may, at step 130, implement the non-uniform access using direct flip-flop to flip-flop connections across dies.

The systems and methods disclosed herein may improve on modern system-on-chip (SoC) design for AR/VR edge devices that may typically include multiple subsystems (e.g., camera interface, machine learning accelerator, graphics processing unit (GPU), central processing unit (CPU), etc.) sharing a large memory (usually SRAM) to pass data between the subsystems. These large, shared memories (e.g., 32+MB) that have equal latencies for all ports and memory endpoints cannot be designed with low energy/access due to large clock tree power and pipelining to overcome the large physical distances signals must travel. 3D stacked memories have been used to increase the memory capacities of such SoCs while maintaining the same X and Y form-factor (i.e., area footprint). These 3D stacked memories (i.e., multiple dies of SRAM stacked directly on top of each other), however, are accessed via a separate connection that cannot simultaneously serve multiple subsystems, thus yielding lower bandwidth connections to memories on other dies compared to the same die. Typically, these memories also require data to be serialized and then de-serialized in order to transfer data from one die to another, which is a power-hungry process.

One bottleneck to AR/VR SoCs is the prohibitive cost of DRAM power consumption, footprint constraints due to form factor requirements, and limited on-chip SRAM per IP due to multiple IPs having to share on-chip SRAM (SMEM). The ability to expand in the z-direction (e.g., 3D vertical integration) allows for additional SRAM per compute IP (e.g., stacked right on top) with high-BW and low-power 3D connections. With this advanced 3D stacking technology, the disclosed systems and methods may achieve multiple benefits including power savings and latency reduction for AR/VR SoCs within tight form factor constraints, and deployment of larger workloads not previously feasible in 2D AR/VR SoCs.

An example AR/VR use case may demonstrate both motivation and challenges with deployment. For example, challenges arise in deploying Image Signal Processing (ISP) on AR/VR devices. Image Signal Processing (ISP) lies in between the camera sensor and the machine learning (ML)/computer vision (CV) pipeline. It may transform raw input image data and improve image quality in augmented reality/virtual reality (AR/VR) applications. However, given these algorithms need to be run on mobile/edge devices, the ISP unit needs to satisfy rigorous requirements across key performance metrics such as power consumption, area, and bandwidth (BW). As shown in FIG. 2 at 200, ISP workloads incur a very large memory footprint (100-700 MB) and require intensive off-chip memory (i.e., DRAM) accesses. As a result, the memory footprint and BW bottleneck may limit the throughput and resolution of ISP algorithms that can be deployed onto AR/VR edge devices, consequently limiting image/video quality and seamless user experiences.

Image processing on mobile devices may usually suffer from a severe “memory wall” bottleneck. Many ISP workloads may have a deep and wide pipeline that demands high memory BW. These pipeline stages may perform heterogeneous tasks and use relatively low computation density. Since these tasks are hardly fused together, they produce a large number of data accesses. For example, to process a full high definition (FHD) video, around 2 GB/s average BW and up to 12 GB/s peak BW may be needed for mobile ISP. Additionally, the ISP workloads may also present large memory footprints in off-chip memory. For instance, a 275 MB uncompressed footprint and 114 MB compressed footprint may arise for FHD video processing. These large memory footprints may result in very expensive off-chip memory accesses. Even worse, with limited I/O pins and area/power budgets in mobile AR/VR devices, it may be difficult for traditional ISP architectures to satisfy the high throughput demands for qualitative image processing. With such large amounts of data stored in DRAM, a significant portion of the system power may be consumed by DRAM accesses. As shown in FIG. 2 at 200, the bandwidth needed for these ISP workloads may range from 1 GB-4 GB, which may lead to 114 mW-395 mW DRAM power consumption. As shown in FIG. 3 at 300, DRAM may consume 48.4%-76.2% of the total system power consumption for the Baseline ISP. Reducing DRAM power consumption may thus lead to substantial power savings in AR/VR devices.

FIG. 4 illustrates an exemplary architecture of a non-uniform memory access across two dies. The disclosed systems and methods may utilize the high density 3D interconnect enabled by hybrid bonding 402 to create a seamless shared memory 400, with non-uniform access times and high bandwidth connections to SRAMs in 3D memory stacks. The disclosed systems and methods may utilize hybrid bonding 402 to create high bandwidth, parallel connections to neighboring dies 408 and 410 with equal bandwidth and access energy compared to conventional on-chip connections. This non-uniform access time may allow for subsystems 404A-404D physically located closer to certain memory (SRAM) banks 406A-406H to have lower latencies but equal bandwidth access to all SRAM banks 406A-406H in the multi-die stack. It may also allow multiple compute units to access a slice of a shared memory at reduced latency/energy compared to a large traditional memory with equal access latency/energy for all memory locations. For example, the energy and latency to access memory two router 412A-412D hops away may be the same, regardless of whether both routers 412A-412D are on the same die or on different dies 408 and 410. Moreover, the bandwidth between two routers 412A-412D can be the same, regardless of whether the routers 412A-412D are located on different dies 408 and 410 or the same die. This design is extendable to multiple die stacks without compromising any given subsystem's 404A-404D access energy to its closest memory banks 406A-406H or the overall bandwidth to each memory bank 406A-406H in the 3D stack. The disclosed systems and methods may avoid using serialize-deserialize circuits (SerDes) when communicating across dies 408 and 410, but rather may use a direct flip-flop to flip-flop connection, minimizing the energy to transmit data across dies 408 and 410. In this context, it may be estimated that only 0.36 pJ/B of the total 3.26 pJ/B (11%) access energy may be attributed to the 3D flip-flop to flip-flop connection. As shown in FIG. 5, the disclosed non-uniform memory access architecture may yield up to 26% access energy reduction even for traversing across dies in the 3D case.

FIG. 6 illustrates exemplary memory technology options considered and proposed for image signal processing hardware 600. The disclosed systems and methods may leverage the opportunities brought by 3D-IC integration and packaging techniques to overcome the limitations of 2D ISP architectures 602 for AR/VR devices. The disclosed systems and methods may increase the memory density within the same footprint using 3D interconnects with low I/O power. 3D integration enables stacking additional memory in the vertical direction with lower latency, lower energy consumption, and higher memory BW.

Given the high memory footprints needed for ISP applications, some implementations of the disclosed systems and methods may use two types of 3D-stacked memory as shown in FIG. 6. For example, some implementations of the disclosed systems and methods may use both 3D SRAM 604 and Wide-IO (WIO) DRAM 606. In this context, 3D SRAM 604 may be achieved by integrating additional SRAM on logic die through TSVs 608, and multiple tiers 610 of SRAM may be used to increase the SRAM capacity without incurring large footprint overheads. WIO DRAM 606 may include an ISP layer 612, a WIO logic layer 614, and DRAM layers 616 vertically connected to the WIO logic layer 614 and/or the ISP layer 612 by TSVs 618. WIO DRAM 606 may use a very large number of pins, each of which may be relatively slow but low powered. With 3D stacking technology, the disclosed systems and methods may increase the number of interconnects substantially compared with 2D solutions. In addition, interconnect/wire distances can be much shorter than typical 2D chips since dies are stacked vertically via short connections, which aids in reducing capacitance and thus power consumption.

An example implementation of the disclosed systems and methods can employ a new modeling methodology for 3D memory allocation and optimization for 3D-stacked ISP architecture for AR/VR-specific applications. Previous modeling methodologies have only used 2D methods/architectures, and DRAM power consumption is too prohibitively expensive for AR/VR use cases. The use of 3D integration offers new 3D image signal processor (ISP) architectural designs and performance benefits for deploying large ISP workloads, which would normally be too power hungry for deployment onto AR/VR edge devices.

The new methodology may be developed on modeling 3D memory for key ISP workloads targeting AR/VR use cases, such as Video ISP+FHD snapshot with/without compression and Video ISP+full-resolution. For modeling the 3D memories, storage density, dynamic (access) energy, and leakage power may be used as parameters for modeling specifications for LPDDR4X, 3D SRAM, and WIO DRAM as shown in Table 1.

TABLE 1

| | LPDDR4X | 3D SRAM | WIO DRAM |
|---|---|---|---|
| Density (MB/mm²) | ~10 | ~4 | ~8.4 |
| Dynamic Energy (pJ/B) | 53~65 | ~2 | ~7.2 |
| Leakage Power (uW/MB) | ~7.8 | ~310 | ~17 |

Given AR/VR devices are uniquely extremely area constrained, implementations of the disclosed systems and methods may maintain the same footprint of the original ISP compute block and adopt different configurations for the 2D/3D architectural configurations to reduce power while maintaining little to no area overhead. FIG. 5 demonstrates power consumption of the different memory configurations. For the 2D cases of Baseline ISP and 2DSRAM_16 MB of additional SRAM, the latter case incurs 4 mm² area overhead. For the 3D cases of 3DSRAM_32 MB (1-tier), 3DSRAM_64 MB (2-tiers), and 3DSRAM_128 MB (4-tiers), 1-tier, 2-tiers, and 4-tiers of SRAM may be configured respectively on top of the ISP logic die with TSV interconnection, and each tier may include 32 MB SRAM. For the WIO DRAM cases of WIO_64 MB, WIO_128 MB, and WIO_256 MB, 64 MB, 128 MB, and 256 MB capacities may be configured, respectively.

For the above case, FIGS. 5 and 7 present the results for each ISP workload's power consumption comparing the aforementioned 3D memory configurations versus the 2D ISP Baseline. As shown, WIO DRAM demonstrates the best power efficiency. With 64 MB/128 MB/256 MB additional WIO DRAM for the ISP unit, the overall power consumption is reduced by 1.41×/1.55×/1.85×. Compared with the ISP baseline, WIO DRAM greatly improves the power efficiency by reducing the DRAM access traffic and, therefore, the DRAM dynamic power. On the other hand, by stacking the ISP with 32 MB/64 MB/128 MB 3D SRAM instead, the overall power consumption can be reduced by 1.32×/1.33×/1.36×. Thus it is observed that even though the 3D SRAM achieves smaller dynamic power consumption, its leakage power, however, contributes a significant amount to the total power consumption. For example, the 3D SRAM leakage may be 5.0%/9.3%/16.4% of the total power consumption.

FIG. 8 illustrates a 3D ISP Architecture Figure of Merit 800 (FoM). As shown in FIG. 8, the FoM 800 may demonstrate application of a metric for evaluating the optimal 3D ISP Architecture across the wide space of 3D memory options. For example, by comparing different memory settings according to the metric of relative power improvement to relative area footprint (FoM=Power improvement/Area), it is observable that 256 MB WIO QRAM can be a good choice considering the trade-off between power efficiency and area overhead for all cases. Moreover, although multi-tier SRAM can offer larger on-chip memory with small footprint overhead, its FoM 800 does not stand out due to the significant leakage power. The choice of this FoM may be uniquely specific to AR/VR devices which may weigh both area and power consumption as equally important for meeting AR/VR edge device requirements.

FIG. 9 illustrates an exemplary comparison 900 of power consumption versus memory capacity across two different types of additional memory for different partitions of the additional memory. By including a hybrid 3D-stacked ISP memory hierarchy and 3D architecture using a combination of 3D SRAM and WIO-DRAM, the disclosed systems and methods can achieve reduced power consumption. For example, the proposed 3D ISP architecture can use a 3D-stacked memory hybrid configuration determined by a 3D modeling tool/methodology. In an example, the 3D ISP memory hierarchy can be partitioned with 25%/50% 3D SRAM and 75%/50% WIO-DRAM to provide optimal power efficiency across dynamic and leakage power. The results of the disclosed ISP architectures are shown in FIG. 9. The hybrid option can provide 23.0%/54.9% improvement compared to using all 3D SRAM and a 6.3%/34.0% improvement compared to using all WIO-DRAM for the different partitions, respectively. For example, a first partition of twenty-five percent 3D SRAM and seventy-five percent WIO-DRAM can provide a twenty-three percent improvement compared to using all 3D SRAM and a six point three percent improvement compared to using all WIO-DRAM. Also, a second partition of fifty percent 3D SRAM and fifty percent WIO-DRAM can provide a fifty-four point nine percent improvement compared to using all 3D SRAM and a thirty-four percent improvement compared to using all WIO-DRAM.

The improvements detailed above indicate that the dynamic/leakage power can be reduced and optimal power efficiency can be achieved by combining both memory technologies and allocating high-throughput data to 3D SRAM. For memory capacities below twenty-five megabytes, the second partition of fifty-percent 3D SRAM and fifty percent WIO-DRAM can be the most power-efficient. For capacities larger than twenty-five megabytes, first partition of twenty-five percent 3D SRAM and seventy-five percent WIO-DRAM can scale much better for power consumption.

The 3D-stacked memory allocation for ISP architecture offers a uniquely flexible way to partition two different types of memories (e.g., 3D SRAM and WIO-DRAM) to balance dynamic power and leakage power, which is not offered by 2D architectures, and across different ISP memory capacity requirements. This partitioning can be extended to other types of 3D-stacked memories.

In terms of scalability, the 3D-stacked memory using 3D SRAM and WIO-DRAM may be extended to other types of 3D memories (e.g., RRAM) and 2.5D solutions like HBM and other DRAM technologies. For example, 2D/2.5D/3D modeling parameters may be integrated into a multi-level memory hierarchy for 3D-stacked ISP architectures to enable even larger ISP workloads requiring even higher memory capacities. Additional implementations of the disclosed systems and methods may stack more than four tiers of 3D memory as permitted by improvements in memory stacking technology and thermal and physical design constraints.

The disclosed systems and methods may further be extended to include scaling compute with memory. For example, beyond 3D-stacked memory architectural designs, implementations of the disclosed systems and methods may stack more ISP compute units on multiple compute tiers in the 3D direction. Thus, if a certain ISP workload requires more compute or if the application requires deployment and running of multiple ISP workloads simultaneously, 3D stacking of compute with memory may enable both lower power consumption and multi-tenancy.

The disclosed systems and methods may further be extended to other workloads and outside of AR/VR use cases. For example, the proposed 3D-stacked memory architecture may be tailored towards a few key ISP workloads being deployed on power and area-constrained AR/VR edge devices, but this methodology and 3D-stacked architecture may be extended to similar workloads that are very memory-intensive and are being deployed on resource-constrained mobile devices. Thus, any specialized accelerator for AR/VR may use this 3D memory allocation strategy.

The disclosed systems and methods may further be extended from statically allocated memory partition to dynamically allocated memory. For example, while the proposed 3D memory allocation strategy described herein may be performed statically and determined before run-time, other implementations may dynamically allocate memory during run-time to support multiple use cases and memory requirements.

As set forth above, the disclosed systems and methods for non-uniform memory access on three-dimensionally stacked hybrid memory may exhibit numerous features and capabilities. For example, the disclosed systems and methods may realize reduced latencies of the memory from each subsystem in a SoC. Additionally, a chip may be fabricated with hybrid-bump technology as a 3DIC system (e.g., observable use of 3D SRAM) or the use of WIO DRAM technology as part of a 3D-stacked architecture. Also, when running an image processing workload on an edge device, the chip may exhibit very low power consumption (e.g., little to no use of DRAM). Further, the chip may exhibit a very small footprint (e.g., using 3D stacked technology) instead of 2D solutions. Finally, a software development kit (SDK) may expose memory allocation to a user (e.g., SRAM, DRAM, etc.) enabling observable use of 3D-stacked memory.

### EXAMPLE EMBODIMENTS

Example 1: A semiconductor device may include a logic die including a circuit and a memory and a plurality of memory dies including an additional memory, wherein the logic die and the plurality of memory dies are stacked three-dimensionally using face-to-face hybrid bonds that provide non-uniform access to the additional memory by the circuit.

Example 2: The semiconductor device of Example 1, wherein the non-uniform access allows one or more subsystem of the circuit to have equal bandwidth access to a plurality of memory banks of the additional memory but with a reduced latency in accessing one or more memory banks of the plurality of memory banks compared to a latency in accessing one or more other memory banks of the plurality of memory banks.

Example 3: The semiconductor device of any of Example 1 and 2, wherein a first latency experienced by a subsystem of the circuit in accessing a memory bank of the additional memory that is a first number of router hops away from the subsystem is less than a second latency experienced by the subsystem in accessing an additional memory bank of the additional memory that is a second number of router hops away from the subsystem, wherein the first number of router hops is less than the second number of router hops.

Example 4: The semiconductor device of any of Example 1 to 3, wherein a first set of energy, latency, and bandwidth experienced by a subsystem of the circuit in accessing a first memory bank of the additional memory that is a given number of router hops away from the subsystem is equal to a second set of energy, latency, and bandwidth experienced by the subsystem in accessing a second memory bank of the additional memory that is the given number of router hops away from the subsystem regardless of whether a first plurality of routers used to access the first memory bank and a second plurality of routers used to access the second memory bank are implemented on a same die, on different dies, or combinations thereof.

Example 5: The semiconductor device of any of Example 1 to 4, wherein the non-uniform access is implemented using direct flip-flop to flip-flop connections across dies.

Example 6: The semiconductor device of any of Example 1 to 5, wherein the additional memory includes a first type of additional memory and a second type of additional memory.

Example 7: The semiconductor device of any of Example 1 to 6, wherein the first type of additional memory corresponds to static random access memory and the second type of additional memory corresponds to wide input-output dynamic random access memory.

Example 8: The semiconductor device of any of Example 1 to 7, wherein the additional memory has a memory capacity no greater than twenty-five megabytes, the first type of additional memory comprises no more than fifty percent of the additional memory, and the second type of additional memory comprises no more than fifty percent of the additional memory.

Example 9: The semiconductor device of any of Example 1 to 8, wherein the additional memory has a memory capacity no less than twenty-five megabytes, the first type of additional memory comprises no more than twenty-five percent of the additional memory, and the second type of additional memory comprises no more than seventy-five percent of the additional memory.

Example 10: The semiconductor device of any of Example 1 to 9, wherein the first type of additional memory and the second type of additional memory are determined by comparing different memory settings according to a metric that evaluates power improvement with respect to area footprint.

Example 11: The semiconductor device of any of Example 1 to 10, wherein a partition of the first type of additional memory and the second type of additional memory is determined by comparing different partitions according to a metric that evaluates power consumption with respect to memory capacity.

Example 12: A method may include providing a logic die including a circuit and a memory, providing a plurality of memory dies including an additional memory, and stacking the logic die and the plurality of memory dies three-dimensionally using face-to-face hybrid bonds that provide non-uniform access to the additional memory by the circuit.

Example 13: The method of Example 1, further including implementing the non-uniform access using direct flip-flop to flip-flop connections across dies.

Example 14: The method of any of Examples 12 and 13, further including including in the additional memory a first type of additional memory and a second type of additional memory.

Example 15: The method of any of Examples 12 to 14, wherein the first type of additional memory corresponds to static random access memory and the second type of additional memory corresponds to wide input-output dynamic random access memory.

Example 16: The method of any of Examples 12 to 15, further including selecting the first type of additional memory and the second type of additional memory by comparing different memory settings according to a metric that evaluates power improvement with respect to area footprint.

Example 17: The method of any of Examples 12 to 16, further including selecting a partition of the first type of additional memory and the second type of additional memory by comparing different partitions according to a metric that evaluates power consumption with respect to memory capacity.

Example 18: A system may include a display device and a semiconductor device configured to process images rendered to the display device, wherein the semiconductor device includes a logic die including a circuit and a memory, and a plurality of memory dies including an additional memory, wherein the logic die and the plurality of memory dies are stacked three-dimensionally using face-to-face hybrid bonds that provide non-uniform access to the additional memory by the circuit.

Example 19: The system of Examples 18, wherein the additional memory includes a first type of additional memory and a second type of additional memory.

Example 20: The method of any of Examples 18 and 19, wherein the first type of additional memory corresponds to static random access memory and the second type of additional memory corresponds to wide input-output dynamic random access memory.

Embodiments of the present disclosure may include or be implemented in conjunction with various types of artificial reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

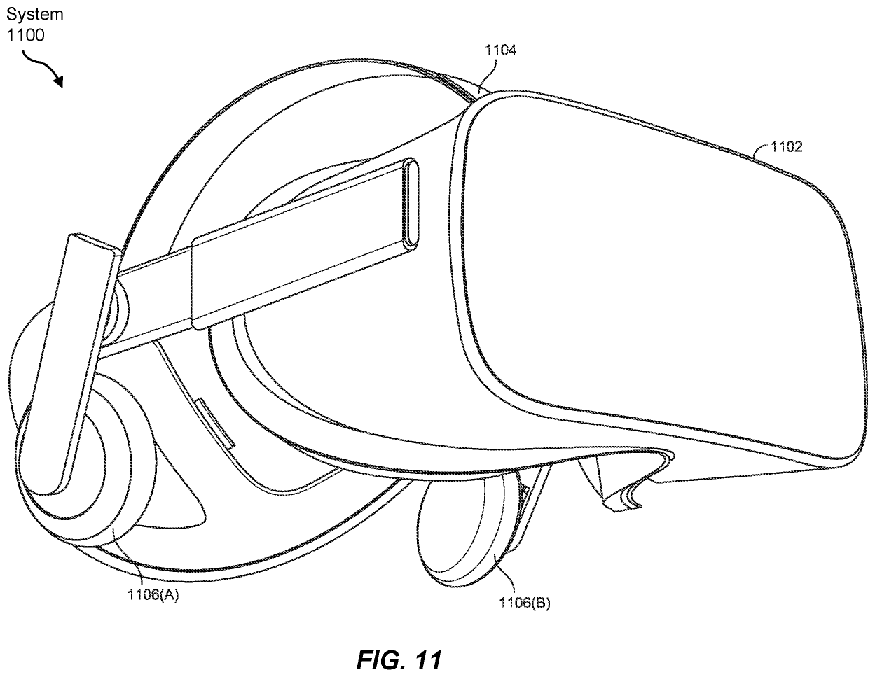

Artificial-reality systems may be implemented in a variety of different form factors and configurations. Some artificial reality systems may be designed to work without near-eye displays (NEDs). Other artificial reality systems may include an NED that also provides visibility into the real world (such as, e.g., augmented-reality system 1000 in FIG. 10) or that visually immerses a user in an artificial reality (such as, e.g., virtual-reality system 1100 in FIG. 11). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 10, augmented-reality system 1000 may include an eyewear device 1002 with a frame 1010 configured to hold a left display device 1015(A) and a right display device 1015(B) in front of a user's eyes. Display devices 1015(A) and 1015(B) may act together or independently to present an image or series of images to a user. While augmented-reality system 1000 includes two displays, embodiments of this disclosure may be implemented in augmented-reality systems with a single NED or more than two NEDs.

In some embodiments, augmented-reality system 1000 may include one or more sensors, such as sensor 1040. Sensor 1040 may generate measurement signals in response to motion of augmented-reality system 1000 and may be located on substantially any portion of frame 1010. Sensor 1040 may represent one or more of a variety of different sensing mechanisms, such as a position sensor, an inertial measurement unit (IMU), a depth camera assembly, a structured light emitter and/or detector, or any combination thereof. In some embodiments, augmented-reality system 1000 may or may not include sensor 1040 or may include more than one sensor. In embodiments in which sensor 1040 includes an IMU, the IMU may generate calibration data based on measurement signals from sensor 1040. Examples of sensor 1040 may include, without limitation, accelerometers, gyroscopes, magnetometers, other suitable types of sensors that detect motion, sensors used for error correction of the IMU, or some combination thereof.

In some examples, augmented-reality system 1000 may also include a microphone array with a plurality of acoustic transducers 1020(A)-1020(J), referred to collectively as acoustic transducers 1020. Acoustic transducers 1020 may represent transducers that detect air pressure variations induced by sound waves. Each acoustic transducer 1020 may be configured to detect sound and convert the detected sound into an electronic format (e.g., an analog or digital format). The microphone array in FIG. 10 may include, for example, ten acoustic transducers: 1020(A) and 1020(B), which may be designed to be placed inside a corresponding ear of the user, acoustic transducers 1020(C), 1020(D), 1020(E), 1020(F), 1020(G), and 1020(H), which may be positioned at various locations on frame 1010, and/or acoustic transducers 1020(I) and 1020(J), which may be positioned on a corresponding neckband 1005.

In some embodiments, one or more of acoustic transducers 1020(A)-(J) may be used as output transducers (e.g., speakers). For example, acoustic transducers 1020(A) and/or 1020(B) may be earbuds or any other suitable type of headphone or speaker.

The configuration of acoustic transducers 1020 of the microphone array may vary. While augmented-reality system 1000 is shown in FIG. 10 as having ten acoustic transducers 1020, the number of acoustic transducers 1020 may be greater or less than ten. In some embodiments, using higher numbers of acoustic transducers 1020 may increase the amount of audio information collected and/or the sensitivity and accuracy of the audio information. In contrast, using a lower number of acoustic transducers 1020 may decrease the computing power required by an associated controller 1050 to process the collected audio information. In addition, the position of each acoustic transducer 1020 of the microphone array may vary. For example, the position of an acoustic transducer 1020 may include a defined position on the user, a defined coordinate on frame 1010, an orientation associated with each acoustic transducer 1020, or some combination thereof.

Acoustic transducers 1020(A) and 1020(B) may be positioned on different parts of the user's ear, such as behind the pinna, behind the tragus, and/or within the auricle or fossa. Or, there may be additional acoustic transducers 1020 on or surrounding the ear in addition to acoustic transducers 1020 inside the ear canal. Having an acoustic transducer 1020 positioned next to an ear canal of a user may enable the microphone array to collect information on how sounds arrive at the ear canal. By positioning at least two of acoustic transducers 1020 on either side of a user's head (e.g., as binaural microphones), augmented-reality system 1000 may simulate binaural hearing and capture a 3D stereo sound field around about a user's head. In some embodiments, acoustic transducers 1020(A) and 1020(B) may be connected to augmented-reality system 1000 via a wired connection 1030, and in other embodiments acoustic transducers 1020(A) and 1020(B) may be connected to augmented-reality system 1000 via a wireless connection (e.g., a BLUETOOTH connection). In still other embodiments, acoustic transducers 1020(A) and 1020(B) may not be used at all in conjunction with augmented-reality system 1000.

Acoustic transducers 1020 on frame 1010 may be positioned in a variety of different ways, including along the length of the temples, across the bridge, above or below display devices 1015(A) and 1015(B), or some combination thereof. Acoustic transducers 1020 may also be oriented such that the microphone array is able to detect sounds in a wide range of directions surrounding the user wearing the augmented-reality system 1000. In some embodiments, an optimization process may be performed during manufacturing of augmented-reality system 1000 to determine relative positioning of each acoustic transducer 1020 in the microphone array.

In some examples, augmented-reality system 1000 may include or be connected to an external device (e.g., a paired device), such as neckband 1005. Neckband 1005 generally represents any type or form of paired device. Thus, the following discussion of neckband 1005 may also apply to various other paired devices, such as charging cases, smart watches, smart phones, wrist bands, other wearable devices, hand-held controllers, tablet computers, laptop computers, other external compute devices, etc.

As shown, neckband 1005 may be coupled to eyewear device 1002 via one or more connectors. The connectors may be wired or wireless and may include electrical and/or non-electrical (e.g., structural) components. In some cases, eyewear device 1002 and neckband 1005 may operate independently without any wired or wireless connection between them. While FIG. 10 illustrates the components of eyewear device 1002 and neckband 1005 in example locations on eyewear device 1002 and neckband 1005, the components may be located elsewhere and/or distributed differently on eyewear device 1002 and/or neckband 1005. In some embodiments, the components of eyewear device 1002 and neckband 1005 may be located on one or more additional peripheral devices paired with eyewear device 1002, neckband 1005, or some combination thereof.

Pairing external devices, such as neckband 1005, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 1000 may be provided by a paired device or shared between a paired device and an eyewear device, thus reducing the weight, heat profile, and form factor of the eyewear device overall while still retaining desired functionality. For example, neckband 1005 may allow components that would otherwise be included on an eyewear device to be included in neckband 1005 since users may tolerate a heavier weight load on their shoulders than they would tolerate on their heads. Neckband 1005 may also have a larger surface area over which to diffuse and disperse heat to the ambient environment. Thus, neckband 1005 may allow for greater battery and computation capacity than might otherwise have been possible on a stand-alone eyewear device. Since weight carried in neckband 1005 may be less invasive to a user than weight carried in eyewear device 1002, a user may tolerate wearing a lighter eyewear device and carrying or wearing the paired device for greater lengths of time than a user would tolerate wearing a heavy standalone eyewear device, thereby enabling users to more fully incorporate artificial reality environments into their day-to-day activities.

Neckband 1005 may be communicatively coupled with eyewear device 1002 and/or to other devices. These other devices may provide certain functions (e.g., tracking, localizing, depth mapping, processing, storage, etc.) to augmented-reality system 1000. In the embodiment of FIG. 10, neckband 1005 may include two acoustic transducers (e.g., 1020(I) and 1020(J)) that are part of the microphone array (or potentially form their own microphone subarray). Neckband 1005 may also include a controller 1025 and a power source 1035.

Acoustic transducers 1020(I) and 1020(J) of neckband 1005 may be configured to detect sound and convert the detected sound into an electronic format (analog or digital). In the embodiment of FIG. 10, acoustic transducers 1020(I) and 1020(J) may be positioned on neckband 1005, thereby increasing the distance between the neckband acoustic transducers 1020(I) and 1020(J) and other acoustic transducers 1020 positioned on eyewear device 1002. In some cases, increasing the distance between acoustic transducers 1020 of the microphone array may improve the accuracy of beamforming performed via the microphone array. For example, if a sound is detected by acoustic transducers 1020(C) and 1020(D) and the distance between acoustic transducers 1020(C) and 1020(D) is greater than, e.g., the distance between acoustic transducers 1020(D) and 1020(E), the determined source location of the detected sound may be more accurate than if the sound had been detected by acoustic transducers 1020(D) and 1020(E).

Controller 1025 of neckband 1005 may process information generated by the sensors on neckband 1005 and/or augmented-reality system 1000. For example, controller 1025 may process information from the microphone array that describes sounds detected by the microphone array. For each detected sound, controller 1025 may perform a direction-of-arrival (DOA) estimation to estimate a direction from which the detected sound arrived at the microphone array. As the microphone array detects sounds, controller 1025 may populate an audio data set with the information. In embodiments in which augmented-reality system 1000 includes an inertial measurement unit, controller 1025 may compute all inertial and spatial calculations from the IMU located on eyewear device 1002. A connector may convey information between augmented-reality system 1000 and neckband 1005 and between augmented-reality system 1000 and controller 1025. The information may be in the form of optical data, electrical data, wireless data, or any other transmittable data form. Moving the processing of information generated by augmented-reality system 1000 to neckband 1005 may reduce weight and heat in eyewear device 1002, making it more comfortable to the user.

Power source 1035 in neckband 1005 may provide power to eyewear device 1002 and/or to neckband 1005. Power source 1035 may include, without limitation, lithium-ion batteries, lithium-polymer batteries, primary lithium batteries, alkaline batteries, or any other form of power storage. In some cases, power source 1035 may be a wired power source. Including power source 1035 on neckband 1005 instead of on eyewear device 1002 may help better distribute the weight and heat generated by power source 1035.

As noted, some artificial reality systems may, instead of blending an artificial reality with actual reality, substantially replace one or more of a user's sensory perceptions of the real world with a virtual experience. One example of this type of system is a head-worn display system, such as virtual-reality system 1100 in FIG. 11, that mostly or completely covers a user's field of view. Virtual-reality system 1100 may include a front rigid body 1102 and a band 1104 shaped to fit around a user's head. Virtual-reality system 1100 may also include output audio transducers 1106(A) and 1106(B). Furthermore, while not shown in FIG. 11, front rigid body 1102 may include one or more electronic elements, including one or more electronic displays, one or more inertial measurement units (IMUs), one or more tracking emitters or detectors, and/or any other suitable device or system for creating an artificial-reality experience.

Artificial reality systems may include a variety of types of visual feedback mechanisms. For example, display devices in augmented-reality system 1000 and/or virtual-reality system 1100 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial reality systems may include a single display screen for both eyes or may provide a display screen for each eye, which may allow for additional flexibility for varifocal adjustments or for correcting a user's refractive error. Some of these artificial reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial reality systems described herein may include one or more projection systems. For example, display devices in augmented-reality system 1000 and/or virtual-reality system 1100 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial reality systems may also be configured with any other suitable type or form of image projection system, such as retinal projectors used in virtual retina displays.

The artificial reality systems described herein may also include various types of computer vision components and subsystems. For example, augmented-reality system 1000 and/or virtual-reality system 1100 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial reality system may process data from one or more of these sensors to identify a location of a user, to map the real world, to provide a user with context about real-world surroundings, and/or to perform a variety of other functions.

The artificial reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial reality devices, within other artificial reality devices, and/or in conjunction with other artificial reality devices.

By providing haptic sensations, audible content, and/or visual content, artificial reality systems may create an entire virtual experience or enhance a user's real-world experience in a variety of contexts and environments. For instance, artificial reality systems may assist or extend a user's perception, memory, or cognition within a particular environment. Some systems may enhance a user's interactions with other people in the real world or may enable more immersive interactions with other people in a virtual world. Artificial reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

What is claimed is:

1. A semiconductor device comprising:
a logic die including a circuit and a memory; and
a plurality of memory dies including an additional memory;
wherein the logic die and the plurality of memory dies are stacked three-dimensionally using face-to-face hybrid bonds that provide non-uniform access to the additional memory by the circuit.

2. The semiconductor device of claim 1, wherein the non-uniform access allows one or more subsystem of the circuit to have equal bandwidth access to a plurality of memory banks of the additional memory but with a reduced latency in accessing one or more memory banks of the plurality of memory banks compared to a latency in accessing one or more other memory banks of the plurality of memory banks.

3. The semiconductor device of claim 1, wherein a first latency experienced by a subsystem of the circuit in accessing a memory bank of the additional memory that is a first number of router hops away from the subsystem is less than a second latency experienced by the subsystem in accessing an additional memory bank of the additional memory that is a second number of router hops away from the subsystem, wherein the first number of router hops is less than the second number of router hops.

4. The semiconductor device of claim 1, wherein a first set of energy, latency, and bandwidth experienced by a subsystem of the circuit in accessing a first memory bank of the additional memory that is a given number of router hops away from the subsystem is equal to a second set of energy, latency, and bandwidth experienced by the subsystem in accessing a second memory bank of the additional memory that is the given number of router hops away from the subsystem regardless of whether a first plurality of routers used to access the first memory bank and a second plurality of routers used to access the second memory bank are implemented on a same die, on different dies, or combinations thereof.

5. The semiconductor device of claim 1, wherein the non-uniform access is implemented using direct flip-flop to flip-flop connections across dies.

6. The semiconductor device of claim 1, wherein the additional memory includes a first type of additional memory and a second type of additional memory.

7. The semiconductor device of claim 6, wherein the first type of additional memory corresponds to static random access memory and the second type of additional memory corresponds to wide input-output dynamic random access memory.

8. The semiconductor device of claim 7, wherein the additional memory has a memory capacity no greater than twenty-five megabytes, the first type of additional memory comprises no more than fifty percent of the additional memory, and the second type of additional memory comprises no more than fifty percent of the additional memory.

9. The semiconductor device of claim 7, wherein the additional memory has a memory capacity no less than twenty-five megabytes, the first type of additional memory comprises no more than twenty-five percent of the additional memory, and the second type of additional memory comprises no more than seventy-five percent of the additional memory.

10. The semiconductor device of claim 6, wherein the first type of additional memory and the second type of additional memory are determined by comparing different memory settings according to a metric that evaluates power improvement with respect to area footprint.

11. The semiconductor device of claim 6, wherein a partition of the first type of additional memory and the second type of additional memory is determined by comparing different partitions according to a metric that evaluates power consumption with respect to memory capacity.

12. A method comprising:
providing a logic die including a circuit and a memory;
providing a plurality of memory dies including an additional memory; and
stacking the logic die and the plurality of memory dies three-dimensionally using face-to-face hybrid bonds that provide non-uniform access to the additional memory by the circuit.

13. The method of claim 12, further comprising:
implementing the non-uniform access using direct flip-flop to flip-flop connections across dies.

14. The method of claim 12, further comprising:
including in the additional memory a first type of additional memory and a second type of additional memory.

15. The method of claim 14, wherein the first type of additional memory corresponds to static random access memory and the second type of additional memory corresponds to wide input-output dynamic random access memory.

16. The method of claim 14, further comprising:
selecting the first type of additional memory and the second type of additional memory by comparing different memory settings according to a metric that evaluates power improvement with respect to area footprint.

17. The method of claim 14, further comprising:
selecting a partition of the first type of additional memory and the second type of additional memory by comparing different partitions according to a metric that evaluates power consumption with respect to memory capacity.

18. A system comprising:
a display device; and
a semiconductor device configured to process images rendered to the display device, wherein the semiconductor device includes:
a logic die including a circuit and a memory; and
a plurality of memory dies including an additional memory,
wherein the logic die and the plurality of memory dies are stacked three-dimensionally using face-to-face hybrid bonds that provide non-uniform access to the additional memory by the circuit.

19. The system of claim 18, wherein the additional memory includes a first type of additional memory and a second type of additional memory.

20. The system of claim 19, wherein the first type of additional memory corresponds to static random access memory and the second type of additional memory corresponds to wide input-output dynamic random access memory.
